(19) United States
(12) Patent Application Publication
(10) Pub. No.: US 2024/0395597 A1
(43) Pub. Date: Nov. 28, 2024

(54) METHOD FOR PERFORMING TRENCH ISOLATION PROCESS

(71) Applicant: TAIWAN SEMICONDUCTOR MANUFACTURING COMPANY, LTD., Hsinchu (TW)

(72) Inventors: Hung-Yu YEN, Hsinchu (TW); Keng-Chu LIN, Hsinchu (TW)

(73) Assignee: TAIWAN SEMICONDUCTOR MANUFACTURING COMPANY, LTD., Hsinchu (TW)

(21) Appl. No.: 18/321,844

(22) Filed: May 23, 2023

(51) Int. Cl. H01L 21/762; H01L 21/324

(52) U.S. Cl. CPC H01L 21/76224; H01L 21/324

(57) ABSTRACT

A method for performing trench filling includes: patterning a base structure to form a plurality of trenches in the patterned base structure; depositing a trench filling material over the patterned base structure to fill the trenches; performing an annealing process at a temperature not greater than 550° C. to anneal the trench filling material; and performing a plasma radical treatment at a temperature not greater than 500° C. to treat the trench filling material.

### BACKGROUND

Trench isolation process is a process performed during fabrication of nanosheet device to prepare for example, but not limited to, shallow trench isolation (STI) element. In order to provide better isolation among nanosheet devices, there are increasing demands on STI elements with improved quality.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for performing a trench isolation process in accordance with some embodiments.

FIGS. 2 to 9 are schematic views illustrating intermediate stages of the method for performing the trench isolation process in accordance with some embodiments.

FIGS. 10 to 11 are schematic views illustrating a semiconductor structure prepared from the structure shown in FIG. 9 in accordance with some embodiments.

FIG. 12 is a graph illustrating germanium levels of channel features for samples of semiconductor structures that are respectively prepared using trench isolation processes performed with different maximum annealing temperatures in accordance with some embodiments.

FIG. 13 is a line graph illustrating resistances gained of the channel features with different germanium levels for the samples of semiconductor structures in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

During a process for forming a trench isolation element, an isolation material may be filled into a trench using a deposition process. In the case that the trench has a relatively high aspect ratio, the isolation material may be subjected to one or more high temperature annealing processes, which may be performed at a temperature higher than about 600° C. (e.g., about 700° C. or above), to improve quality of the isolation element so as to avoid collapse of a dummy gate disposed on the isolation element and to avoid merge of epitaxial portions (e.g., source/drain elements of two adjacent devices). With advancement of semiconductor devices, the performance requirements of the semiconductor devices have become increasingly stringent.

The present disclosure is directed to a method for performing trench filling in the field of semiconductor structure fabrication. The method for trench filling may include patterning a base structure to form a plurality of trenches in the patterned base structure; depositing a trench filling material over the patterned base structure to fill the trenches; performing an annealing process to anneal the trench filling material; and performing a plasma radical treatment to treat the trench filling material. By virtue of the annealing process and the plasma radical treatment, the trench filling material is formed into a trench filling element having desirable quality. It is noted that the annealing process and the plasma radical treatment each may be performed at a relatively low temperature, such as not greater than about 550° C., so that the semiconductor structure produced thereby may have a better device performance.

Exemplarily, such trench filling technique may be applied in, for example, but not limited to, a trench isolation process during manufacturing of the semiconductor structure to form an isolation element (i.e., the trench filling element) in the trenches. The isolation element may be a shallow trench isolation (STI) element, a deep trench isolation (DTI) element, or other suitable isolation elements. The semiconductor structure may be a nanosheet semiconductor structure, such as a gate-all-around (GAA) nanosheet, a field effect transistor (FET), a forksheet structure, a complementary field-effect transistor (CFET), or other suitable semiconductor structures. In accordance to the present disclosure, the trench isolation process is performed at a relatively low temperature, so that the semiconductor structure obviates a deterioration of device performance. For instance, the semiconductor structure produced using the trench isolation process of the present disclosure may have a relatively low level of channel resistance, in addition to other enhanced mobility related electrical parameter(s). Meanwhile, such isolation element achieves an excellent quality to avoid collapse of other elements in the semiconductor structure (e.g., a dummy gate) or merge of source/drain elements of the semiconductor structure.

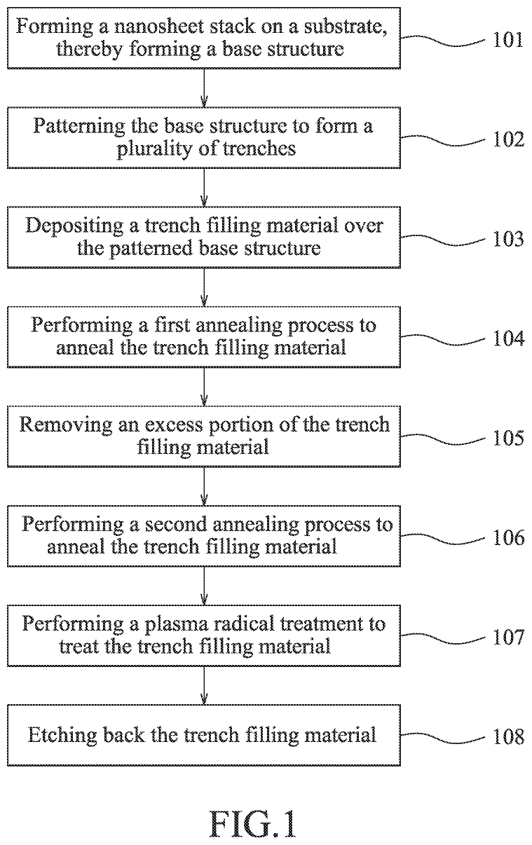

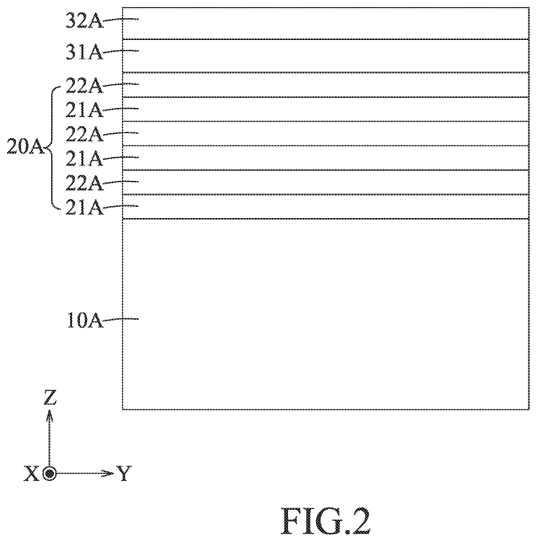

FIG. 1 is a flow diagram illustrating a method for performing a trench isolation process to obtain a plurality of isolation elements formed in trenches in accordance with some embodiments, while FIGS. 2 to 9 are schematic views illustrating intermediate stages thereof. Some repeating structures are omitted in FIGS. 2 to 9 for the sake of brevity. Additional steps can be provided before, after or during the method, and some of the steps described herein may be replaced by other steps or be eliminated.

Referring to FIG. 1 and the example illustrated in FIG. 2, the method begins at step 101, where a nanosheet stack 20A is formed on a substrate 10A to form a base structure.

The substrate 10A may be made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The substrate 10A may be doped with p-type impurities or n-type impurities, or undoped. In addition, the substrate 10A may be a bulk silicon substrate, a silicon-on-insulator (SOI) substrate, or a germanium-on-insulator (GOI) substrate. Other suitable materials for the substrate 10A are within the contemplated scope of disclosure.

The nanosheet stack 20A includes a plurality of sacrificial layers 21A, and a plurality of channel layers 22A disposed to alternate with the sacrificial layers 21A in a Z direction transverse to both X and Y directions. In some embodiments, the X, Y, and Z directions are perpendicular to one another. A number of the sacrificial layers 21A and a number of the channel layers 22A are determined according to practical requirements. In the exemplary example shown in FIG. 2, the number of the sacrificial layers 21A is equal to the number of the channel layers 22A, and is three. Suitable materials for the sacrificial layers 21A and the channel layers 22A are similar to those for the substrate 10A, but the sacrificial layers 21A are made of a material different from that of the channel layers 22A. In some embodiments, the sacrificial layers 21A are made of silicon germanium (SiGe) and the channel layers 22A are made of silicon (Si). Other suitable materials for the sacrificial layer 21A and the channel layers 22A are within the contemplated scope of disclosure.

In some embodiments, the base structure further includes a hard mask unit formed on the nanosheet stack 20A opposite to the substrate 10A. The hard mask unit may include one or more hard mask(s). In the exemplary example shown in FIG. 2, the hard mask unit includes a first hard mask 31A disposed on the nanosheet stack 20A, and a second hard mask 32A disposed on the first hard mask 31A. The first and second hard masks 31A. 32A are made of different dielectric materials, such as silicon oxide, silicon nitride, aluminum oxide, silicon oxynitride, or combinations thereof. In some embodiments, the first hard mask 31A is made of silicon nitride (SiN), and the second hard mask 32A is made of an oxide, such as silicon oxide. Other suitable materials for the first and second hard masks 31A, 32A are within the contemplated scope of disclosure.

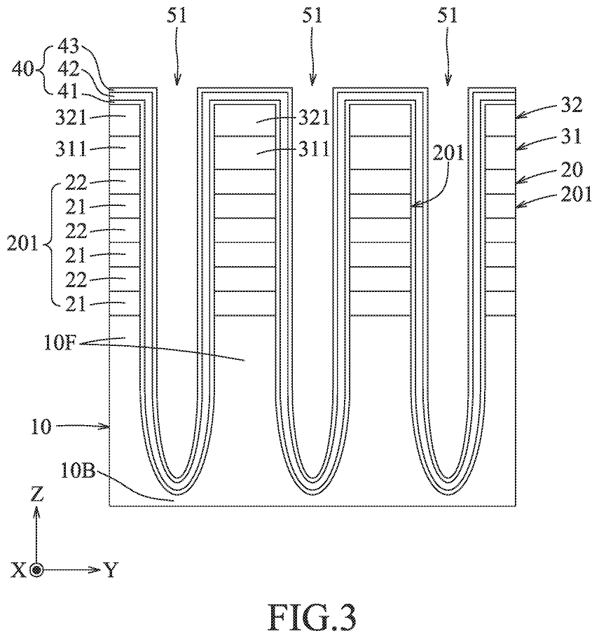

Referring to FIG. 1 and the example illustrated in FIG. 3, the method proceeds to step 102, where the base structure shown in FIG. 2 is patterned such that a plurality of trenches 51 are formed in the patterned base structure. Hereinafter, the patterned substrate is denoted by the numeral 10, the patterned nanosheet stack is denoted by the numeral 20, the patterned first hard mask is denoted by the numeral 31, and the patterned second hard mask is denoted by the numeral 32. In some embodiments, each of the trenches 51 extends through the patterned first and second hard masks 31, 32, the patterned nanosheet stack 20, and into the patterned substrate 10. Please note that a number of the trenches 51 may be determined according to practical needs. In the exemplary example shown in FIG. 3, the number of the trenches 51 is 3. The patterned substrate 10 includes a base portion 10B and a plurality of fin portions 10F which are spaced apart from each other in the Y direction. The patterned nanosheet stack 20 includes a plurality of stack portions 201 respectively disposed on the fin portions 10F. Each of the stack portions 201 includes a plurality of sacrificial portions 21 (respectively obtained from patterning the sacrificial layers 21A) and a plurality of the channel portions 22 (respectively obtained from patterning the channel layers 22A). The patterned first hard mask 31 includes a plurality of first mask portions 311 respectively formed on the stack portions 201. The patterned second hard mask 32 includes a plurality of second mask portions 321 respectively formed on the first mask portions 311.

A patterning process used in step 102 may be any suitable etching process, such as dry etching, wet etching, reactive ion etching (RIE), or the like, or combinations thereof. Other suitable processes for patterning the base structure are within the contemplated scope of disclosure.

In some embodiments, after formation of the trenches 51, and prior to step 103, a dielectric liner element 40 is formed over the patterned base structure. The dielectric liner element 40 may protect the fin portions 10F and the patterned nanosheet stack 20 from damage during other processes performed subsequently.

In some embodiments, the dielectric liner element 40 includes a silicon liner 41 formed over the patterned base structure, and an oxygen-including liner 42 formed over the silicon liner 41. In some embodiments, the oxygen-including liner 42 is made of an oxygen-including material in combination with at least one of silicon, carbon and/or nitrogen, such as silicon oxynitride (SiON), silicon oxycarbonitride (SiOCN), silicon oxide (SiOₓ). In certain embodiments, the silicon liner 41 may have a thickness ranging from about 2 nm to about 5 nm. In certain embodiments, the oxygen-including liner 42 may have a thickness greater than 0 nm and less than about 10 nm. The silicon liner 41 and the oxygen-including liner 42 may be formed by any suitable deposition process, such as atomic layered deposition (ALD), but is not limited thereto. Other suitable materials and/or thickness ranges and/or deposition processes for forming the silicon liner 41 and the oxygen-including liner 42 are within the contemplated scope of disclosure. In yet other embodiments, the dielectric liner element 40 further includes an another silicon liner 43 that is similar to the silicon liner 41 and that is formed over the oxygen-including liner 42. In still other embodiments, the oxygen-including liner 42 is first formed over the patterned base structure, and the silicon liner 41 is formed over the oxygen-including liner 42.

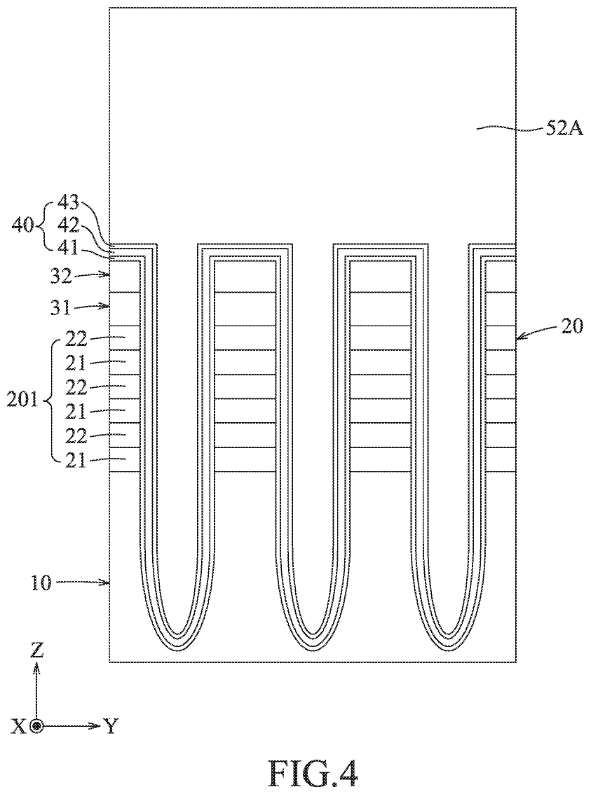

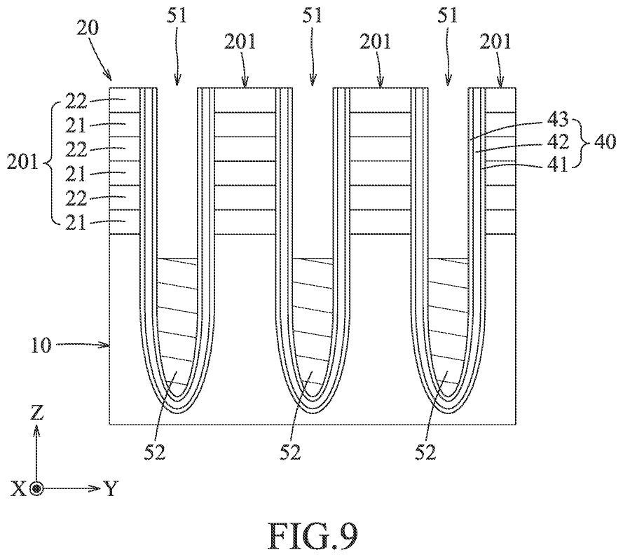

Referring to FIG. 1 and the example illustrated in FIG. 4, the method proceeds to step 103, where a trench filling material is deposited over the patterned base structure and the dielectric liner element 40 to form a filling layer 52A that fills the trenches 51 shown in FIG. 3. The filling layer 52A is to be formed into a plurality of isolation elements 52 (see FIG. 9) that are respectively disposed in the trenches 51.

In certain embodiments, the trench filling material is a silicon-based dielectric material, such as silicon carbon oxynitride (SiCON), silicon oxide (SiO), silicon nitride (SiN), silicon carbide (SiC), silicon oxycarbide (SiCO), silicon carbonitride (SiCN), silicon oxynitride (SiON), or combinations thereof, but are not limited thereto. In some embodiments, the deposited trench filling material may have a thickness ranging from about 3200 Å to about 4000 Å. The trench filling material is deposited using any suitable deposition process, such as chemical vapor deposition (CVD), flowable CVD (FCVD), or high density plasma CVD (HDPCVD), but are not limited thereto. In some embodiments, a FCVD process is adopted for depositing the trench filling material so that the deposited material has a flowable nature so as to flow into the trenches 51 shown in FIG. 3, thereby beneficially minimize amount of voids or seams present in the isolation elements 52. In some embodiments, when the FCVD process is adopted, the trench filling material deposited is a flowable nitride-containing material (i.e., a nitride-like material, such as silicon carbon oxynitride (SiCON), silicon nitride (SiN), silicon carbide (SIC), silicon oxycarbide (SiCO), silicon carbonitride (SiCN), silicon oxynitride (SiON)), and a certain amount of Si—N bonding is present in the trench filling material. In certain embodiments, the FCVD process is performed at a temperature ranging from about −20° C. to about 100° C. and at a pressure ranging from about 0.1 Torr to about 600 Torr. In certain embodiments, the FCVD process may utilize any suitable precursors, such as a silylamine-based material, or carrier gas, or additives, to reach a desired composition serving as the trench filling material. In certain embodiments, a plasma process may also be used to assist the deposition. Other suitable materials and/or deposition processes of the trench filling material are within the contemplated scope of disclosure. The aforementioned deposition parameters may be adjusted according to practical needs.

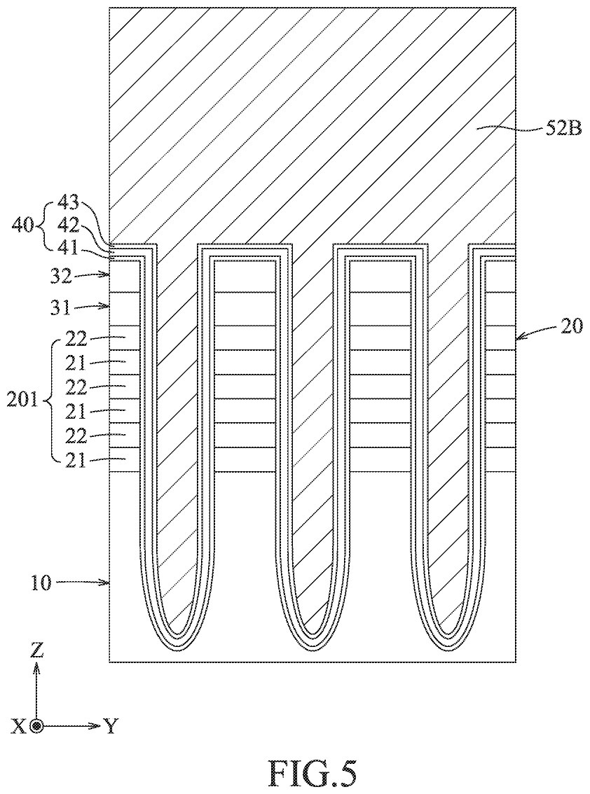

Referring to FIG. 1 and the example illustrated in FIG. 5, the method proceeds to step 104, where a first annealing process is performed to anneal the trench filling material, so that the filling layer 52A (see FIG. 4) is formed into an annealed filling layer 52B.

In some embodiments, the first annealing process is performed at a temperature approximately not greater than about 550° C., such as not greater than about 500° C. In other embodiments, the first annealing process is performed at a temperature ranging from about 350° C. to about 550° C. In some embodiments, the first annealing process is performed at a pressure ranging from about 1 atm to about 25 atm. In some embodiments, the first annealing process is performed in a furnace and in presence of a water steam. In some embodiments, the first annealing process may be performed for a time period ranging from about 2 hours to about 24 hours. The aforementioned annealing parameters may be adjusted according to practical needs. After the first annealing process, Si—N bonding in the trench filling material, especially the trench filling material located at an upper portion of the filling layer 52A, is converted into Si—O bonding (and the nitrogen may react with hydrogen and leave the filling layer 52A). In addition, the annealed filling layer 52B is strengthened and densified compared with the filling layer 52A.

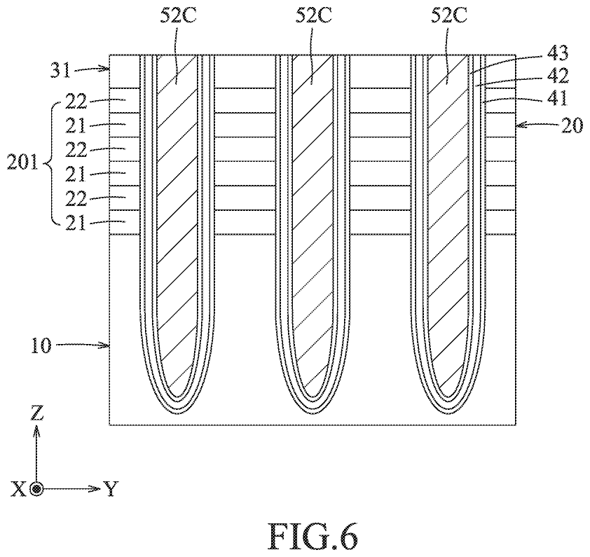

Referring to FIG. 1 and the example illustrated in FIG. 6, the method proceeds to step 105, where an excess portion of the trench filling material is removed to leave a portion of the trench filling material remaining in the trenches 51 (see FIG. 3). That is, a removal process is performed on the annealed filling layer 52B as shown in FIG. 5, so that the annealed filling layer 52B is formed into a plurality of trench filling structures 52C.

The removal process used in step 105 may be any suitable techniques, such as a planarization process, but is not limited thereto. In some embodiments, the removal process may be a chemical-mechanical planarization (CMP) process. Other suitable processes for removal of the excess portion of the trench filling material are within the contemplated scope of disclosure.

In some embodiments, referring to the exemplary example shown in FIGS. 5 and 6, when the CMP process is adopted, the first hard mask 31 made of SiN may serve as an etch stop layer, so that the excess portion of the trench filling material in the annealed filing layer 52B is removed, along with the second hard mask 32 made of SiO, and a portion of the dielectric liner element 40 disposed on the second hard mask 32. As such, the remaining portion of the trench filling material forms the trench filling structures 52C that are respectively disposed in the trenches 51 (see FIG. 3). As shown in FIG. 6, the trench filling structures 52C may be flush with the first hard mask 31. In some embodiments, the trench filling structures 52C may each have a thickness ranging from about 1600 Å to about 2200 Å.

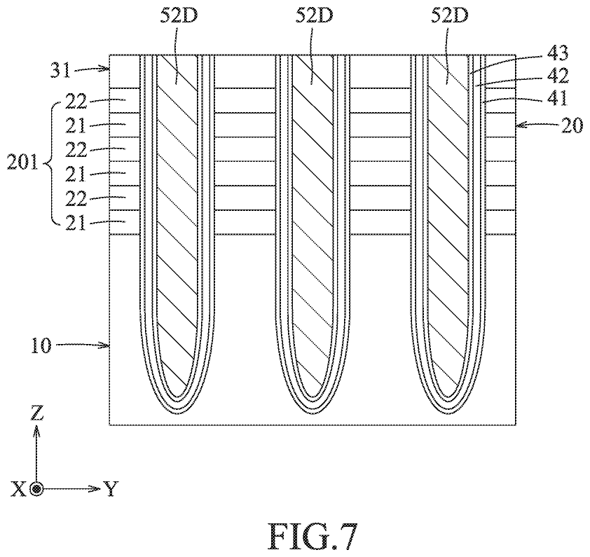

Referring to FIG. 1 and the example illustrated in FIG. 7, the method proceeds to step 106, where a second annealing process is performed to further anneal the trench filling material remaining in the trenches 51 (see FIG. 3), and the trench filling structures 52C shown in FIG. 6 are respectively formed into annealed trench filling structures 52D.

In some embodiments, annealing parameters of the second annealing process may be similar to that of the first annealing process described in step 104 with reference to FIG. 5, and details thereof are omitted for the sake of brevity. In other embodiments, the aforementioned annealing parameters of the second annealing process may also be different from that of the first annealing process.

In addition to the first annealing process performed in step 104, the second annealing process is conducive to further convert Si—N bonding in the trench filling material, especially the trench filling material located at a bottom portion of each of the filling structures 52C, into Si—O bonding, and to further strengthen and densify the trenching filling material, so as to obtain the annealed trench filling structures 52D. It is noted that performing the annealing process twice (i.e., the first and second annealing processes) may be beneficial to provide the isolation elements 52 with better quality (see FIG. 9), especially when the trenches 51 are narrow, or have a high aspect ratio.

In some embodiments, step 106 may be omitted.

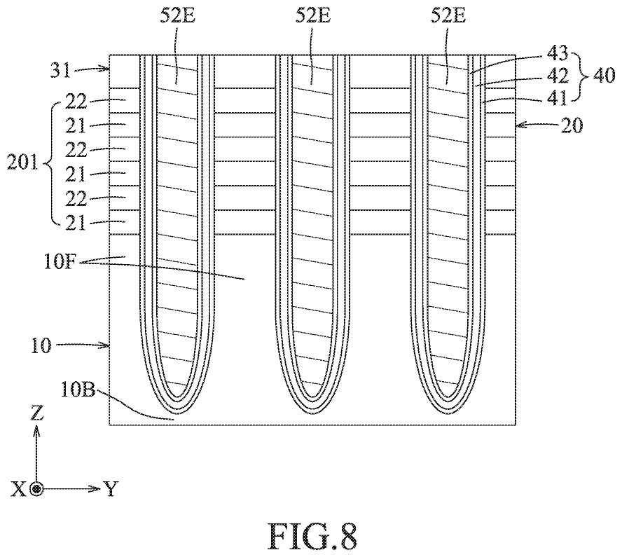

Referring to FIG. 1 and the example illustrated in FIG. 8, the method proceeds to step 107, where a plasma radical treatment is performed to treat the trench filling material, and the annealed trench filling structures 52D shown in FIG. 7 are respectively formed into treated trench filling structures 52E.

The plasma radical treatment may be performed at a temperature not greater than about 500° C., such as approximately not greater than 400° C. In some embodiments, the plasma radical treatment is performed at a temperature ranging from about 350° C. to about 500° C. It is noted that when the temperature is too high, the structure shown in FIG. 7, especially the fin portions 10F, may be undesirably damaged, and that when the temperature is too low, reactivity of the radicals is undesirably insufficient.

In the plasma radical treatment of step 107, a plasma is generated from a precursor gas including oxygen gas and a carrier gas. The carrier gas may include argon gas and/or helium gas. The oxygen gas is converted into radicals so as to treat the trenching filling material by further converting any Si—N bonding into Si—O bonding. In some embodiments, the precursor gas may further include hydrogen gas, so that the plasma generated may further include hydroxyl radicals which are noted to have longer lifetime and deeper penetration into the trenching filling material compared with the lifetime and penetration by oxygen radicals, and thus have even better performance in terms of bonding conversion.

The plasma radical treatment may include, such as inductively coupled plasma (ICP), capacitively coupled plasma (CCP), microwave (MW) plasma, or the like, but are not limited thereto.

The plasma radical treatment may be performed with a plasma source power ranging from about 0.5 kW to about 5 kW. The plasma source power is applied for generating the plasma. Thus, when the plasma source power is too low, the plasma may not be generated. When the plasma source power is too high, the structure shown in FIG. 7 may be undesirably damaged.

The plasma radical treatment may be performed for a time period ranging from about 10 seconds to about 999 seconds. It is noted that when the time period is too short, the quality of the treated trench filling structures 52E is not satisfying, and that when the time period is too long, the structure shown in FIG. 7 may be undesirably damaged. In some embodiments, the plasma radical treatment is performed from about 10 seconds to about 60 seconds. In certain embodiments, the plasma radical treatment is performed from about 61 seconds to about 300 seconds. In other embodiments, the plasma radical treatment is performed from about 301 seconds to about 999 seconds.

The plasma radical treatment may be performed with a plasma bias ranging from about 10 W to about 999 W. The plasma bias provides a power that controls the energy of radicals (generated in the plasma) bombarding the trench filling material during step 107. It is noted that when the plasma bias is too low, the plasma radical treatment is not effective, and that when the plasma bias is too high, the structure shown in FIG. 7 may be undesirably damaged. In some embodiments, the plasma bias ranges from about 10 W to about 100 W. In certain embodiments, the plasma bias ranges from about 101 W to about 300 W. In other embodiments, the plasma bias ranges from about 301 W to about 999 W.

The plasma radical treatment may be performed at a pressure ranging from about 10 mTorr to about 100 Torr. It is noted that when the pressure is too low, the structure shown in FIG. 7 may be undesirably damaged, and when the pressure is too high, a density of the plasma generated is insufficient.

In some embodiments, as described above, the plasma radical treatment is performed after the second annealing process (step 106). Alternatively, in other embodiments, the plasma radical treatment may also be performed prior to the second annealing process (step 106) and after removing the excess portion of the trench filling material (step 105). In yet other embodiments, the plasma radical treatment may also be performed after the first annealing process (step 104) and prior to removing the excess portion of the trench filling material (step 105), so as to avoid any underlying element(s) (e.g., the substrate 10) from being undesirably damaged during the plasma radical treatment.

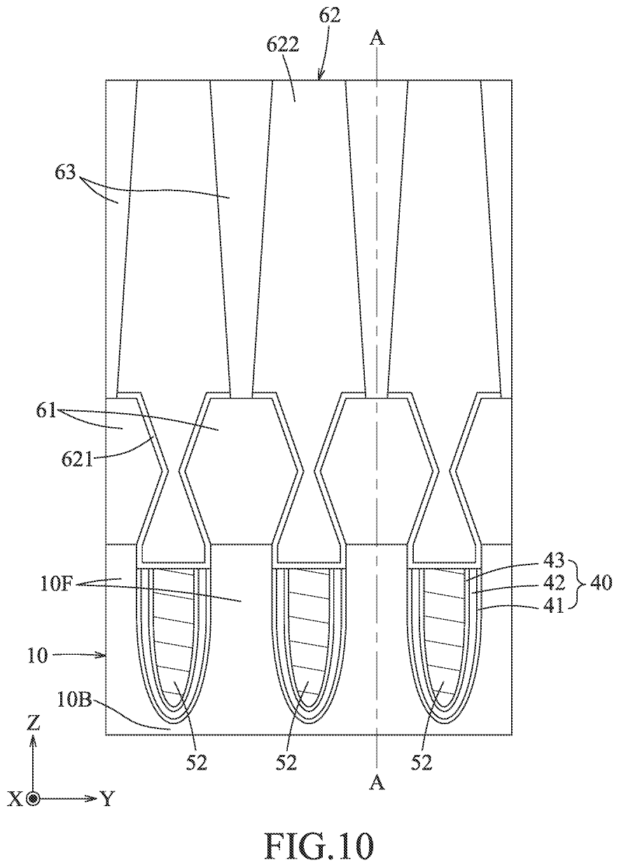

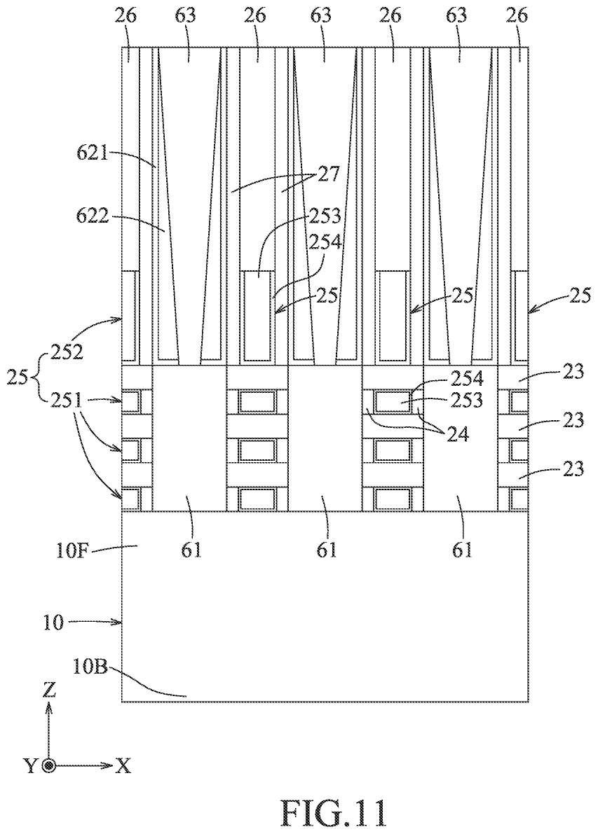

By including the first and second annealing processes, and the plasma radical treatment in trench isolation process, the isolation elements 52 (see FIG. 9) produced according to the method of the present disclosure may have an oxygen content greater than that of the filling layer 52A, suggesting that cooperatively performing these steps (i.e., steps 104, 106 and 107) is effective to convert Si—N bonding in the trench filling material into Si—O bonding, i.e., the nitride-like trench filling material deposited in step 103 is converted into an oxide-like trench filling material after step 107. In some embodiments, the isolation elements 52 may have an oxygen atomic concentration greater than about 70%. The oxide-like trench filling material, after step 107, may include silicon oxide and/or silicon peroxide (SiOx, x greater than 2, and x may become 2 when the isolation elements 52 are subjected to further processes, e.g., fabrication of a semiconductor structure). In addition, the isolation elements 52 obtained are strengthened and densified compared with the filling layer 52A shown in FIG. 4. The isolation elements 52 obtained by steps 104, 106 and 107 are of good quality, e.g., having smooth and flat upper surface, and having sufficient strength to avoid collapse of dummy gates (not shown, which are to be replaced by upper gate features 252 shown in FIG. 11) in subsequent fabrication of the semiconductor structure or merge of source/drain elements (e.g., source/drain portions 61 as shown in FIGS. 10 and 11) of the semiconductor structure. Furthermore, such trench isolation process is reproducible to provide similar and high quality isolation elements 52.

Referring to FIG. 1 and the example illustrated in FIG. 9, the method proceeds to step 108, where the trench filling material is etched back. That is, the trench filling structures 52E shown in FIG. 8 are recessed to obtain the isolation elements 52.

The etching back of the trench filling material may be performed using any suitable techniques, such as dry etching, but is not limited thereto. The isolation elements 52 are formed to have a predetermined height. In the exemplary example shown in FIG. 9, the isolation elements 52 are each at a level lower that the bottommost one of the sacrificial portions 21. In some embodiments, the isolation elements 52 may each have a thickness ranging from about 1000 Å to about 1600 Å. In some embodiments, the first hard mask 31 (see FIG. 8), and the dielectric liner element 40 disposed thereon are also removed in this step, leaving the uppermost one of the channel portions 22 exposed.

By completion of step 108, the trench isolation process is considered completed.

In some embodiments, after step 108, based on the design of the isolation elements 52, a nitride cap layer (not shown) is formed over the oxide-like trench filling material. In certain embodiments, for an upper portion of each of the isolation elements 52, the oxide-like trench filling material is converted into a nitride by performing for example, but not limited to, an another plasma radical treatment. A precursor gas of nitrogen gas and carrier gas may be used. Other parameters, such as the plasma bias, for the another plasma radical treatment may be adjusted accordingly so as to bombard and convert the Si—O bonding located at the upper portion of the isolation elements 52 into Si—N bonding, thereby form the nitride cap layer. As such, the isolation elements 52 may each have a lower portion and the upper portion (the nitride cap layer which may be much thinner than the lower portion, such as ranging from 0 to less than about 20 Å). The lower portion has a higher oxygen content than that of the upper portion, and the upper portion has a higher nitrogen content than that of the lower portion.

In some embodiments, to obtain a semiconductor structure, such as a GAA structure shown in FIGS. 10 and 11, the structure shown in FIG. 9 may be subjected to the following processes (i) to (viii). FIG. 10 is a cross-sectional view along the Y direction of the GAA structure in accordance with some embodiments. FIG. 11 is a cross-sectional view taken line A-A of FIG. 10 in accordance with some embodiments. It should be noted that the GAA structure may further include additional features, and/or some features present therein may be modified, replaced, or eliminated without departure from the spirit and scope of the present disclosure.

In each of the following processes (i) to (viii), one or more deposition processes (such as CVD, atomic layer deposition (ALD), other suitable processes, or combinations thereof), one or more photolithography processes for forming patterned photomask(s) or patterned hark mask(s) (such as coating a photoresist, exposing the photoresist through a photomask, developing the photoresist, etching using the photoresist, stripping the photoresist, and/or other suitable processes), one or more etching processes for patterning (such as dry etching, wet etching, other suitable processes, combinations thereof), and/or one or more planarization processes (such as, CMP, or other suitable processes) may be used, but not limited thereto.

In process (i), a plurality of the dummy gates (not shown), which extend respectively in the Y direction to partially cover the stack portions 201 shown in FIG. 9 and which are spaced apart from each other in the X direction, are formed over the structure shown in FIG. 9. Each of the dummy gates may include a dummy electrode (which may be made of polysilicon or other suitable materials), a dummy dielectric (which may be made of silicon oxide or other suitable materials and which is disposed between the dummy electrode and the structure shown in FIG. 9), and two gate spacers 27 (see FIG. 11) (which may be made of silicon nitride or other suitable materials, and which are formed at two opposite sides of a stack of the dummy electrode and the dummy dielectric).

In process (ii), parts of the stack portions 201 (which are exposed from the dummy gates) and first parts of the dielectric liner element 40 (which are exposed from the dummy gates and the isolation elements 52) are removed to form a plurality of source/drain recesses (not shown) such that each of the stack portions 201 is patterned into a plurality of stack elements (not shown). Each of the stack elements are patterned into a plurality of channel features 23 (see FIG. 11) and a plurality of sacrificial features (not shown). The channel features 23 of the stack elements in each of the stack portions 201 are obtained from patterning the channel portions 22 of a corresponding one of the stack portions 201 shown in FIG. 9, and the sacrificial features of the stack elements in each of the stack portions 201 are obtained from patterning the sacrificial portions 21 of a corresponding one of the stack portions 201 shown in FIG. 9.

In process (iii), two opposite ends along the X direction of each of the sacrificial features in each of the stack elements are replaced with two inner spacers 24. The inner spacers 24 may be made of silicon oxide, silicon nitride, silicon oxynitride, high dielectric constant materials, other suitable materials, or combinations thereof.

In process (iv), the source/drain portions 61 (see FIGS. 10 and 11) are respectively formed in the source/drain recesses. The source/drain portions 61 may be made of an epitaxial semiconductor material, and may each be independently doped with impurities. The source/drain portions 61 may refer to a source or a drain, individually or collectively dependent upon the context.

In process (v), a plurality of dielectric units 62 are each formed to cover corresponding ones of the source/drain portions 61, which are displaced from each other in the Y direction (see FIG. 10). Each of the dielectric units 62 may include a contact etch stop layer (CESL) 621 disposed over the corresponding source/drain portions 61 and an interlayer dielectric (ILD) layer 622 disposed over the CESL 621. The ILD layer 622 and the CESL 621 may each be made of a dielectric material different from each other. The dielectric material may be silicon oxide, silicon nitride, or the like, or combinations thereof, but are not limited thereto. Other materials suitable for the ILD layer 622 and CESL 621 are within the contemplated scope of the present disclosure.

In process (vi), the dummy electrodes and the dummy dielectrics of the dummy gates are removed to form a plurality of upper cavities (not shown), and then, the remaining sacrificial features in the stack elements and second parts of the dielectric liner element 40 (which are located aside the remaining sacrificial features) are removed to form a plurality of lower cavities (not shown, which are in positions corresponding to the stack elements, and which are respectively beneath the upper cavities).

In process (vii), a plurality of active gates 25 (see FIG. 11) are each formed in one of the lower cavities and a corresponding one of the upper cavities. Each of the active gates includes a lower gate feature 251 formed in one of the lower cavities and an upper gate feature 252 formed in a corresponding one of the upper cavities. Each of the lower and upper gate features 251, 252 includes a gate electrode 253 and a gate dielectric 254 surrounding the gate electrode 253. The provision of the gate dielectrics 254 of the active gates 25 and the inner spacers 24 can separate the gate electrodes 253 of the active gates 25 from the source/drain portions 61. In some embodiments, an upper portion of the upper gate feature 252 for each of the active gates 25 may be replaced by a respective one of self-aligned contacts (SAC) 26 (see FIG. 11). The gate electrode 253 may include aluminum, tungsten, copper, other suitable materials, or combinations thereof. The gate dielectric 254 may include silicon oxide, silicon nitride, silicon oxynitride, high dielectric constant materials, or combinations thereof. The SACs 26 may include a low dielectric material. Other suitable materials for forming the upper and lower gate features 251, 252 and the SACs 26 are within the contemplated scope of the present disclosure.

In process (viii), a plurality of source/drain contacts 63 (see FIGS. 10 and 11) are formed in each of the dielectric units 62 so as to be in contact with corresponding ones of the source/drain portions 61. The source/drain contacts 63 may be made of a conductive material such as copper, tungsten, cobalt, ruthenium, aluminum, palladium, nickel, platinum, a low resistivity metal constituent, or the like, or combinations thereof, but are not limited thereto. Other materials suitable for the source/drain contacts 63 are within the contemplated scope of the present disclosure.

In some embodiments, after performing processes (i) to (viii), the materials of the remaining silicon liner 41 and another silicon liner 43 shown in FIG. 10 may be converted into silicon oxide.

The isolation elements 52 of the GAA structure prepared using the aforementioned trench isolation process of the present disclosure possess desirable quality, and the GAA structure produced thereby is noted to have good device performance. More specifically, the trench isolation process of the present disclosure includes the plasma radical treatment (step 107) in addition to the first and second annealing processes (step 104 and 106), which are all performed at a relatively low temperature (approximately not greater than 550° C.). The following descriptions illustrate the significance of a low temperature annealing process during the trench isolation process in connection with resistance of channel features of the GAA structure produced thereby. Four samples of GAA structures are prepared in a similar manner, except that during the trench isolation process in preparation of each of the samples, annealing of the trench filling material is performed with different maximum annealing temperatures, i.e., at T1, T2, T3 and T4, respectively, wherein T4<T3<T2<T1 (the samples are respectively labeled as T1, T2, T3 and T4). In each of the four samples, the sacrificial layers 21A shown in FIG. 2 (i.e., the sacrificial portions 21 shown in FIGS. 3 to 9) are made of silicon germanium, and the channel layers 22A shown in FIG. 2 (i.e., the channel portions 22 shown in FIGS. 3 to 9 and the channel features shown in FIG. 11) are made of silicon. During formation of the isolation elements 52, diffusion of germanium (Ge) in the sacrificial portions 21 into the channel portions 22 may affect a resistance of the channel features 23.

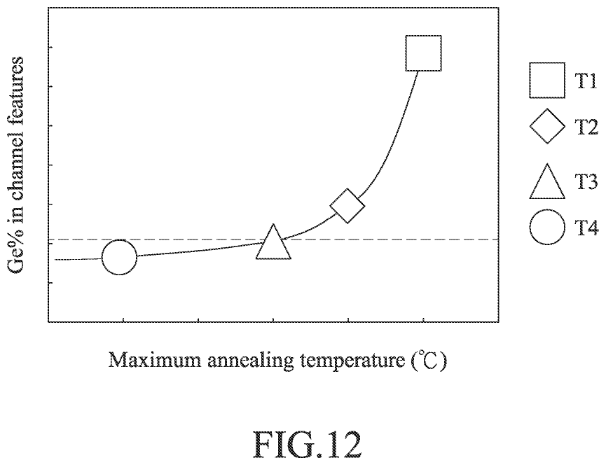

FIG. 12 illustrates, for the channel features of each of the four samples of GAA structures, the Ge level (in terms of atomic percentage of the channel features) with respective to the maximum annealing temperature of the trench filling material in accordance with some embodiments. It is found that the Ge level of the channel features reduces with reduced maximum annealing temperature.

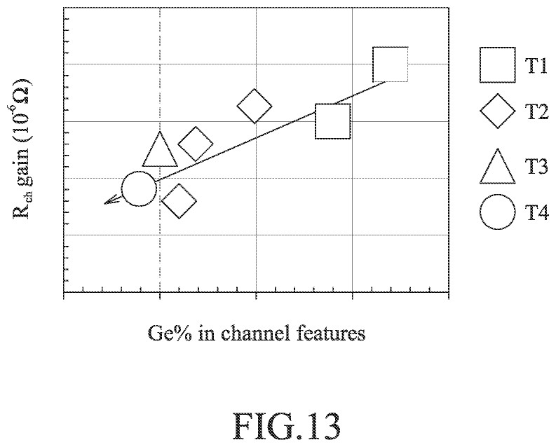

FIG. 13 is a line graph illustrating resistances gained of the channel features with different germanium levels for the samples of semiconductor structures in accordance with some embodiments. In FIG. 13, the resistance of the channel features of GAA structure of T1 is taken as a reference point in calculation of the resistance gained (R_{ch} gain in 10⁻⁶Ω) for the channel features of the other three samples (T2, T3, T4) of GAA structures. It is found that the resistances gained by the channel features of GAA structures of T2, T3 and T4 are all negative, i.e., the resistances of the channel features of T2, T3 and T4 are indeed reduced compared with that of T1. In addition, it is noted that the resistance of the channel features reduces with reduced Ge level of the channel features.

The findings in FIGS. 12 and 13 show that when annealing of the trench filling material is performed at a relatively low temperature (e.g., T4), the Ge diffusion from SiGe sacrificial portions to Si channel portions during annealing of the trench filling material is less, and the Ge level present in the channel features (which are formed from the channel portions in steps subsequent to the annealing of the trench filling material) of the GAA is also relatively low so as to retain a relatively large size of Si channel features. As such, the resistance of the channel features of the GAA could be kept as low as possible. Thus, it could be concluded that annealing process performed at a relatively low temperature during the trench isolation process is conducive to lowering the Ge level and the resistance of channel features of the GAA structure, thereby enhancing device performance of the GAA structure. Other mobility related electrical parameters of the GAA structure may also be improved.

In order to obtain channel features with a predetermined desired Ge level (represented by dash lines in FIGS. 12 and 13), in the trench isolation process of the present disclosure, the first and second annealing processes (steps 104 and 106) are each performed at a temperature approximately not greater than about 550° C., so as to minimize Ge diffusion from the sacrificial portions 21 into the channel portions 22. In addition, the trench isolation process of the present disclosure further includes the plasma radical treatment in step 107, so as to further strengthen and densify the trench filling material to thereby produce the isolation elements 52 with good quality.

Please note that the aforementioned trench isolation process used to prepare the trench isolation elements 52 is merely an example to demonstrate the trench filling method of the present disclosure. The trench filling method may also be applied in any other suitable applications for fabrication of semiconductor structures (and is not limited to GAA structure), especially when the trench filling method is required to be conducted at low temperature condition.

The embodiments of the present disclosure have the following advantageous features. With inclusion of the plasma radical treatment, and the first and second annealing processes, the trench filling method of the present disclosure, with a simple process flow conducted at a relatively low temperature (e.g. not greater than about 550° C.), produces a good quality trench filling element, and at the same time device performance of the semiconductor structure manufactured using such trench filling method is well assured.

In accordance with some embodiments of the present disclosure, a method for performing trench filling includes: patterning a base structure to form a plurality of trenches in the patterned base structure; depositing a trench filling material over the patterned base structure to fill the trenches; performing an annealing process at a temperature not greater than 550° C. to anneal the trench filling material; and performing a plasma radical treatment at a temperature not greater than 500° C. to treat the trench filling material.

In accordance with some embodiments of the present disclosure, the method further includes, prior to depositing the trench filling material, forming a dielectric liner element over the patterned base structure.

In accordance with some embodiments of the present disclosure, deposition of the trench filling material is performed by depositing a flowable nitride-containing material.

In accordance with some embodiments of the present disclosure, a precursor gas for generating a plasma used in the plasma radical treatment includes oxygen gas.

In accordance with some embodiments of the present disclosure, the precursor gas further includes hydrogen gas.

In accordance with some embodiments of the present disclosure, the annealing process is performed in presence of a water steam.

In accordance with some embodiments of the present disclosure, a method for performing trench filling includes: patterning a base structure to form a plurality of trenches in the patterned base structure; depositing a trench filling material over the patterned base structure to fill the trenches; performing a first annealing process at a temperature not greater than 550° C. to anneal the trench filling material; removing an excess portion of the trench filling material to leave a portion of the trench filling material remaining in the trenches; performing a second annealing process at a temperature not greater than 550° C. to further anneal the trench filling material remaining in the trenches; and performing a plasma radical treatment at a temperature not greater than 500° C. to treat the trench filling material.

In accordance with some embodiments of the present disclosure, the plasma radical treatment is performed after the second annealing process to treat the trench filling material.

In accordance with some embodiments of the present disclosure, the plasma radical treatment is performed prior to the second annealing process and after removing the excess portion of the trench filling material.

In accordance with some embodiments of the present disclosure, a method for performing a trench isolation process includes: patterning a base structure including a nanosheet stack and a substrate such that the patterned base structure includes a plurality of trenches, each of the trenches extending through the patterned nanosheet stack and into the patterned substrate; depositing a trench filling material over the patterned base structure to fill the trenches; performing an annealing process at a temperature not greater than 550° C. to anneal the trench filling material; and performing a plasma radical treatment at a temperature not greater than 500° C. to treat the trench filling material.

In accordance with some embodiments of the present disclosure, the method further includes: after the annealing process and prior to the plasma radical treatment, removing an excess portion of the trench filling material to leave a portion of the trench filling material remaining in the trenches; and performing an another annealing process at a temperature not greater than 550° C. to further anneal the trench filling material.

In accordance with some embodiments of the present disclosure, the plasma radical treatment is performed after performing the another annealing process.

In accordance with some embodiments of the present disclosure, the plasma radical treatment is performed prior to the another annealing process and after removing the excess portion of the trench filling material.

In accordance with some embodiments of the present disclosure, the method further includes, prior to depositing the trench filling material, forming a dielectric liner element over the patterned base structure.

In accordance with some embodiments of the present disclosure, forming the dielectric liner element includes forming a silicon liner over the patterned base structure, followed by forming an oxygen-including liner over the silicon liner.

In accordance with some embodiments of the present disclosure, forming the dielectric liner element further includes, after forming the oxygen-including liner, forming an another silicon liner over the oxygen-including liner.

In accordance with some embodiments of the present disclosure, each of the silicon liner and the another silicon liner independently has a thickness ranging from 2 nm to 5 nm.

In accordance with some embodiments of the present disclosure, the trench filling material is a silicon-based dielectric material.

In accordance with some embodiments of the present disclosure, a precursor gas for generating a plasma used in the plasma radical treatment includes oxygen.

In accordance with some embodiments of the present disclosure, the precursor gas further includes hydrogen gas.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for performing trench filling, comprising:
patterning a base structure to form a plurality of trenches in the patterned base structure;
depositing a trench filling material over the patterned base structure to fill the trenches;
performing an annealing process at a temperature not greater than 550° C. to anneal the trench filling material; and
performing a plasma radical treatment at a temperature not greater than 500° C. to treat the trench filling material.

2. The method according to claim 1, further comprising, prior to depositing the trench filling material, forming a dielectric liner element over the patterned base structure.

3. The method according to claim 1, wherein deposition of the trench filling material is performed by depositing a flowable nitride-containing material.

4. The method according to claim 3, wherein a precursor gas for generating a plasma used in the plasma radical treatment includes oxygen gas.

5. The method according to claim 4, wherein the precursor gas further includes hydrogen gas.

6. The method according to claim 1, wherein the annealing process is performed in presence of a water steam.

7. A method for performing trench filling, comprising:
patterning a base structure to form a plurality of trenches in the patterned base structure;
depositing a trench filling material over the patterned base structure to fill the trenches;
performing a first annealing process at a temperature not greater than 550° C. to anneal the trench filling material;
removing an excess portion of the trench filling material to leave a portion of the trench filling material remaining in the trenches;
performing a second annealing process at a temperature not greater than 550° C. to further anneal the trench filling material remaining in the trenches; and
performing a plasma radical treatment at a temperature not greater than 500° C. to treat the trench filling material.

8. The method according to claim 7, wherein the plasma radical treatment is performed after the second annealing process to treat the trench filling material.

9. The method according to claim 7, wherein the plasma radical treatment is performed prior to the second annealing process and after removing the excess portion of the trench filling material.

10. A method for performing a trench isolation process, comprising:
patterning a base structure including a nanosheet stack and a substrate such that the patterned base structure includes a plurality of trenches, each of the trenches extending through the patterned nanosheet stack and into the patterned substrate;
depositing a trench filling material over the patterned base structure to fill the trenches;
performing an annealing process at a temperature not greater than 550° C. to anneal the trench filling material; and
performing a plasma radical treatment at a temperature not greater than 500° C. to treat the trench filling material.

11. The method according to claim 10, further comprising:
after the annealing process and prior to the plasma radical treatment, removing an excess portion of the trench filling material to leave a portion of the trench filling material remaining in the trenches; and
performing an another annealing process at a temperature not greater than 550° C. to further anneal the trench filling material.

12. The method according to claim 11, wherein the plasma radical treatment is performed after performing the another annealing process.

13. The method according to claim 11, wherein the plasma radical treatment is performed prior to the another annealing process and after removing the excess portion of the trench filling material.

14. The method according to claim 10, further comprising, prior to depositing the trench filling material, forming a dielectric liner element over the patterned base structure.

15. The method according to claim 14, wherein forming the dielectric liner element includes forming a silicon liner over the patterned base structure, followed by forming an oxygen-including liner over the silicon liner.

16. The method according to claim 15, wherein forming the dielectric liner element further includes, after forming the oxygen-including liner, forming an another silicon liner over the oxygen-including liner.

17. The method according to claim 16, wherein each of the silicon liner and the another silicon liner independently has a thickness ranging from 2 nm to 5 nm.

18. The method according to claim 10, wherein the trench filling material is a silicon-based dielectric material.

19. The method according to claim 18, wherein a precursor gas for generating a plasma used in the plasma radical treatment includes oxygen.

20. The method according to claim 19, wherein the precursor gas further includes hydrogen gas.
